(19) United States
(12) Patent Application Publication
(10) Pub. No.: US 2011/0221006 A1
(43) Pub. Date: Sep. 15, 2011

(54) NAND ARRAY SOURCE/DRAIN DOPING SCHEME

(75) Inventors: Chun Chen, San Jose, CA (US); Shenqing Fang, Fremont, CA (US)

(73) Assignee: Spansion LLC, Sunnyvale, CA (US)

(21) Appl. No.: 12/722,014

(22) Filed: Mar. 11, 2010

(51) Int. Cl. H01L 27/088; H01L 21/8239

(52) U.S. Cl. 257/390; 438/275; 257/E27.06; 257/E21.645

(57) ABSTRACT

An electronic device includes a substrate having isolation features defining active regions coextending over a surface of the substrate. The device also includes coextending line patterns crossing over the active regions, including string and ground selection lines and word lines between the string and ground selection lines. The device further includes first implant regions of a first conductivity type in the active regions between the word lines and having a first carrier concentration. The device further includes second implant regions of the first conductivity type in the active regions between edge ones of the word lines and an adjacent one of the string selection line and the ground selection line. In the device, the second implant region includes a low doping portion abutting the edge word lines and a high doping portion spaced from the edge word line by the low doping portion and having a second carrier concentration greater than the first carrier concentration.

### BACKGROUND OF THE INVENTION

1. Statement of the Technical Field

The invention is directed to the field of memory devices in electronic systems, and more particularly, to non-volatile memory devices in electronic systems.

2. Description of the Related Art

One difficulty in the fabrication of sub-micron NAND-type flash memory devices is short channel effects. That is, if the source/drain (S/D) regions of some devices in the NAND-type memory array are doped to a level high enough to give a reasonably low series resistance, the magnitude of the electric field in the channel adjacent to such S/D regions will be high when the device is active. In general, the electric field can be sufficiently high to cause hot carriers and impact ionization effects which will affect device overall performance, including data retention in the memory cells of the memory array. Therefore, as the channel length of the device decreases, the gate of the device loses control to the channel, which leads to excessive leakage current between device source and drain.

There are several conventional approaches to addressing short channel effects field-effect transistors devices, such as NAND-type memory cells. One approach is to grade the junction of the S/D regions in the devices in the memory by using two implants in an lightly doped drain (LDD) process. A first implant is used to create a lightly doped S/D regions between the devices in the memory array. A second implant is then used to further increase doping in the S/D regions, but the second implant is offset with a sidewall spacer. Another approach is simply to do two implants of different ion species in the same S/D region, where the different masses result in a graded drain doping.

### BRIEF DESCRIPTION OF THE DRAWINGS

Non-limiting and non-exhaustive embodiments of the invention are described with reference to the following drawings, in which:

FIG. 1 is an equivalent circuit diagram showing a portion of a cell array region of a typical NAND-type flash memory device in accordance with an embodiment of the invention;

FIG. 2 is a top plan view of a substrate 200 including the NAND-type flash memory device 100 in FIG. 1 according to an embodiment of the invention;

FIG. 3 is a cross-sectional view illustrating the exemplary method of fabricating a NAND-type flash memory device according to one embodiment of the invention, along the line III-III of FIG. 2;

FIG. 4 is a cross-sectional views illustrating the exemplary method of fabricating a NAND-type flash memory device according to one embodiment of the invention, along the line IV-IV of FIG. 2;

FIG. 5 shows the result of forming a dielectric layer(s) on the structures shown in FIG. 4 in accordance with an embodiment of the invention;

FIG. 6 shows the results of performing a spacer etch process on the dielectric layer 502 of FIG. 5 and subsequent implantation of impurities in accordance with an embodiment of the invention;

FIG. 7 is a portion of a cross section view of the substrate in FIG. 6 after the NAND-type memory array and other device regions are formed thereon;

FIG. 8 is a plan view of a device 800 in accordance with an embodiment of the invention; and

FIG. 9 shows an exemplary electronic systems 900 in accordance with an embodiment of the invention.

### DETAILED DESCRIPTION

The invention is described with reference to the attached figures, wherein like reference numbers are used throughout the figures to designate similar or equivalent elements. The figures are not drawn to scale and they are provided merely to illustrate the instant invention. Several aspects of the invention are described below with reference to example applications for illustration. It should be understood that numerous specific details, relationships, and methods are set forth to provide a full understanding of the invention. One having ordinary skill in the relevant art, however, will readily recognize that the invention can be practiced without one or more of the specific details or with other methods. In other instances, well-known structures or operations are not shown in detail to avoid obscuring the invention. The invention is not limited by the illustrated ordering of acts or events, as some acts may occur in different orders and/or concurrently with other acts or events. Furthermore, not all illustrated acts or events are required to implement a methodology in accordance with the invention.

The word “exemplary” is used herein to mean serving as an example, instance, or illustration. Any aspect or design described herein as “exemplary” is not necessarily to be construed as preferred or advantageous over other aspects or designs. Rather, use of the word exemplary is intended to present concepts in a concrete fashion. As used in this application, the term “or” is intended to mean an inclusive “or” rather than an exclusive “or”. That is, unless specified otherwise, or clear from context, “X employs A or B” is intended to mean any of the natural inclusive permutations. That is if, X employs A; X employs B; or X employs both A and B, then “X employs A or B” is satisfied under any of the foregoing instances.

Briefly stated, embodiments of the invention are related to methods for manufacturing electronic systems including memory cell devices and systems thereof. As described above, one of the problems with NAND-type flash memory arrays is that as the dimensions of the devices is reduced, such devices begin to suffer from short channel effects. Therefore, conventional manufacturing processes for integrated circuits (ICs) including NAND-type flash memory arrays typically utilize an LDD process to grade doping in all the devices within the memory array. However, implementing a such conventional LDD process can lead to problems in the NAND-type memory arrays. First, since only a portion of each of the S/D regions has a high carrier concentration and comprises a deep junction and the geometry for NAND-type flash memory devices is smaller as compared to other devices in the IC, S/D region resistances can become significant. Further, in regions between select gates and memory cell gates, the reduced dimensions also increase the overall string resistance, giving rise to increased parasitic string resistances in the NAND-type memory array.

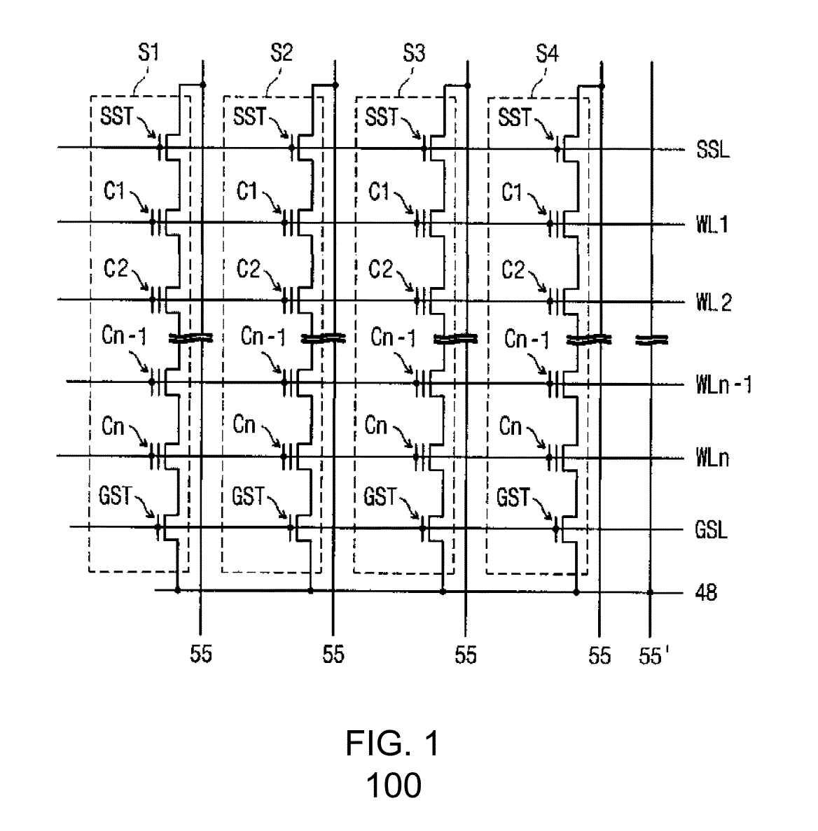

In view of the limitations of such conventional manufacturing methods and systems, the embodiments of the invention provide a novel doping scheme for electronic systems including NAND-type memory arrays. In particular, the various embodiments of the invention provide for forming a NAND-type memory array in which implant regions with a high doping levels are limited to the contact regions adjacent to select gates and to regions between select gates and memory cells. Thus, implant regions with lower doping levels are formed in regions between memory cells. As a result, short-channel effects are minimized in the memory cells while contact resistance and parasitic string resistance are reduced for the array. In the various embodiments of the invention, the novel doping scheme is provided by increasing a spacing between the select gates and memory cells. Further, a spacer process is added that defines high doping implant areas for S/D regions associated with the select gates and that defines an implant mask for S/D regions between memory cells. An exemplary process is illustrated below with respect to FIGS. 1 to 7.

FIG. 1 is an equivalent circuit diagram showing a portion of NAND-type flash memory device 100 in accordance with an embodiment of the invention. As shown in FIG. 1, a cell array region of a NAND-type flash memory device includes a plurality of strings, for example, first to fourth strings S1, S2, S3 and S4. Each of strings S1-S4 includes a string selection transistor SST, a plurality of cell transistors C1 to Cn, and a ground selection transistor GST. In accordance with a NAND-type flash memory configuration, SST, C1-Cn, and GST are connected in series in each of strings S1-S4. In the embodiment illustrated in FIG. 1, each cell transistor has a stacked gate pattern, which includes a floating gate and a control gate electrode. The gate electrodes of the respective string selection transistors SST are electrically connected to a string selection line SSL. Similarly, gate electrodes of the respective ground selection transistors GST are electrically connected to a ground selection line GSL. Also, all the control gate electrodes of the first cell transistors C1 in the plurality of strings are electrically connected to a first word line WL1, all the control gate electrodes of the second cell transistors C2 in the plurality of strings are electrically connected to a second word line WL2, and so forth. The string selection line SSL, the plurality of word lines WL1 to WLn, and the ground selection line GSL are disposed in parallel.

As in a conventional NAND-type memory array, the drain regions of the string selection transistors SST are electrically connected to a plurality of bit lines 55 respectively, and source regions of the ground selection transistors GST are electrically connected to a common source line 48. The plurality of bit lines 55 are also disposed across the plurality of word lines WL1 to WLn. Further, the common source line 48 runs parallel with the ground selection line GSL. Additionally, the common source line 48 can be electrically connected to a metal interconnection 55′, which can run parallel with the bit lines 55. The metal interconnection 55′ acts as an interconnection line for connecting the common source line 48 to a peripheral circuit (not shown).

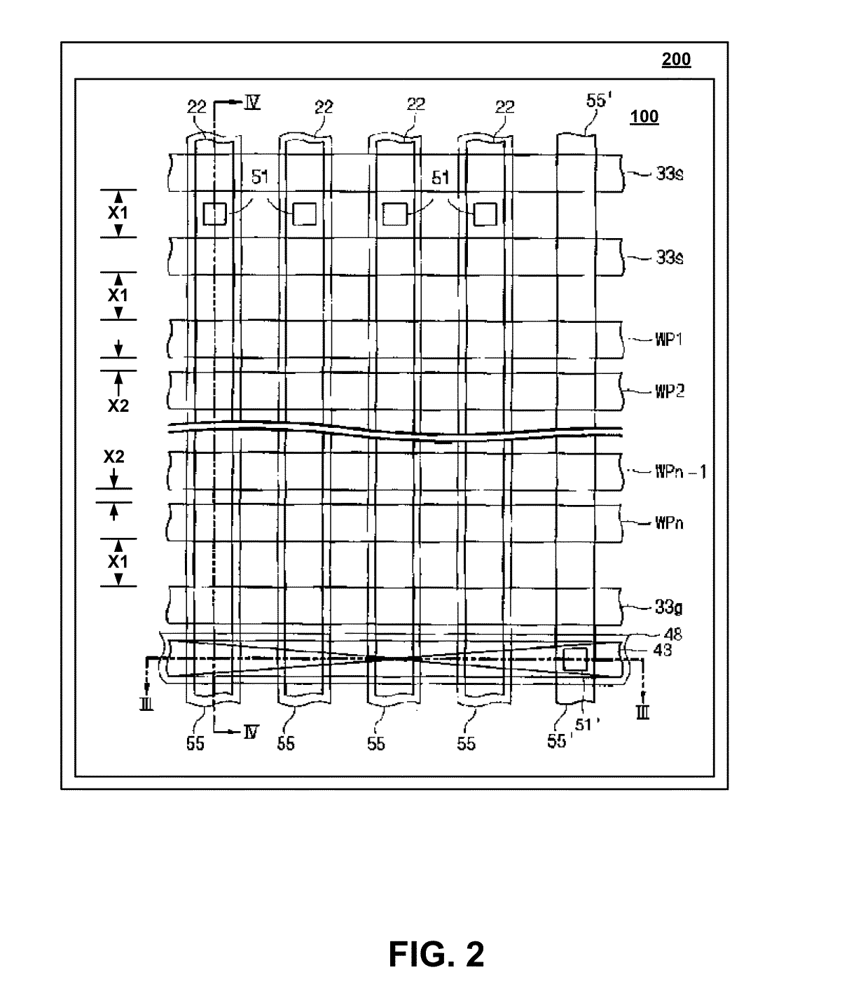

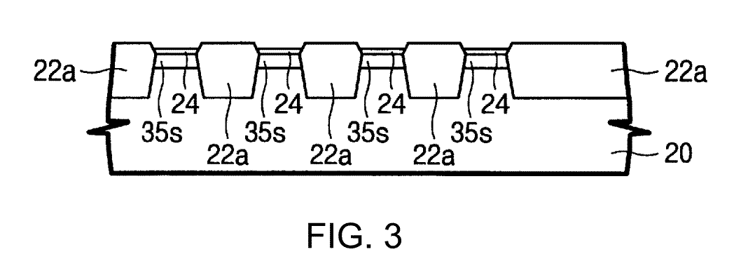

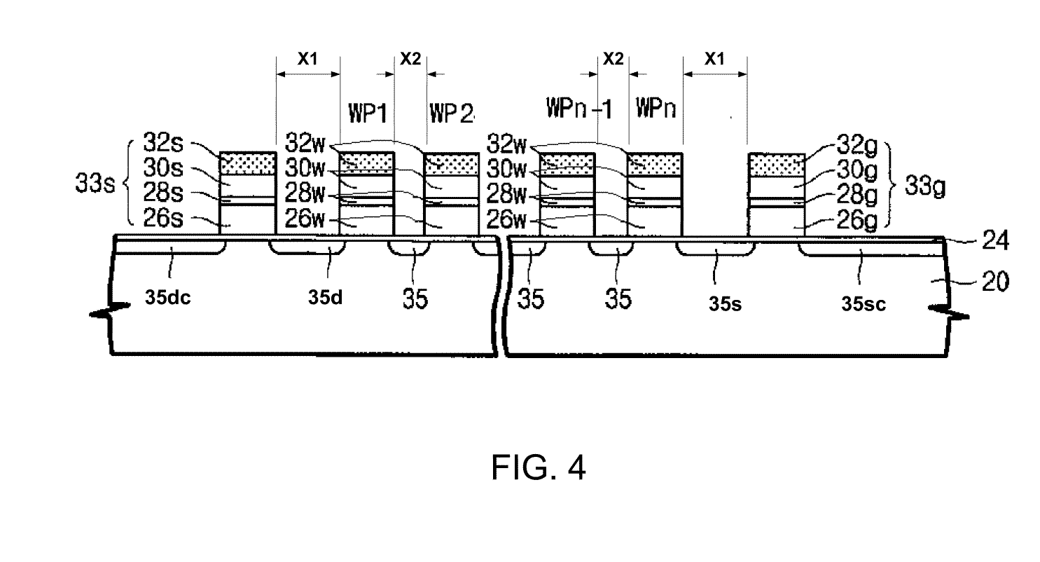

FIG. 2 is a top plan view of a substrate 200 including the NAND-type flash memory device 100 in FIG. 1 according to an embodiment of the invention. FIG. 3 is a cross-sectional view illustrating the exemplary method of fabricating a NAND-type flash memory device according to one embodiment of the invention, along the line III-III of FIG. 2. FIG. 4 is a cross-sectional view illustrating the exemplary method of fabricating a NAND-type flash memory device according to one embodiment of the invention, along the line IV-IV of FIG. 2.

As shown in FIGS. 2-4, the NAND-type memory array 100 includes a plurality of coextending active regions 22 formed in portions of the semiconducting surface of the substrate 200. The term “coextending”, as used herein to describe two or more objects or features, refers to objects or features that extend in parallel directions or substantially parallel directions (directions with ≦10° difference). The plurality of active regions 22 are defined by forming an isolation features 22a at a portion of substrate 200, as shown in FIG. 3. The isolation layer 22a can be formed using any conventional isolation technique, for example, a LOCOS (local oxidation of silicon) process or a trench isolation process. However, the invention is not limited in this regard and other isolation techniques can be used in the various embodiments of the invention. A tunnel oxide layer 24 is formed on the active regions. The tunnel oxide layer 24 can have a thickness of 100 A or less.

A string selection line pattern 33s and a ground selection line pattern 33g cross over the active areas 22, the isolation features 22a and the tunnel oxide layer 24 to define select gates for each string in the array 100. Also, a plurality of word line patterns, WP1 to WPn, also cross over the active areas 22, the isolation features 22a and the tunnel oxide layer 24 to define select gates for each string in the array 100. The plurality of word line patterns WP1 to WPn are disposed between the string selection line pattern 33s and the ground selection line pattern 33g. Thus, the string selection line pattern 33s, the plurality of word line patterns WP1 to WPn and the ground selection line pattern 33g are coextending.

As shown in FIG. 4, the string selection line pattern 33s comprises a string selection line 26s (corresponding to SSL of FIG. 1), an inter-gate dielectric layer 28s, a dummy gate electrode 30s and capping layer pattern 32s which are sequentially stacked. Similarly, the ground selection line pattern 33g comprises a ground selection line 26g (corresponding to GSL of FIG. 1), an inter-gate dielectric layer 28g, a dummy gate electrode 30g and capping layer pattern 32g which are sequentially stacked, as shown in FIG. 4.

Further, each of word line patterns WP1-WPn comprises a floating gate 26w, an intergate dielectric layer 28w, a control gate electrode 30w, and capping layer pattern 32w which are sequentially stacked, as shown in FIG. 4. Here, the floating gates 26w are defined by the portion of the word line patterns WP1-WPn that overlap with active regions 22. The capping layer patterns 32s, 32w and 32g can all be formed using insulating layers. Such insulating layers can include, but are not limited to a silicon nitride layers, silicon oxynitride layers, or silicon oxide layers. In some embodiments, string selection line pattern 33s, the plurality of word line patterns WP1-WPn, and the ground selection line pattern 33g can exclude capping layers 32s, 32w and 32g, respectively.

In the illustrated embodiment, the composition of the string selection line pattern 33s, the plurality of word line patterns WP1-WPn, and the ground selection line pattern 33g is identical. However, the various embodiments of the invention are not limited in this regard. Accordingly, the string selection line pattern 33s and the ground selection line pattern 33g can have a different composition as compared to the plurality of word line patterns WP1-WPn. For example, the string selection line pattern 33s and the ground selection line pattern 33g can comprise one or more electrode layers without a floating gate layer there between.

Once string selection line pattern 33s, the plurality of word line patterns WP1-WPn, and the ground selection line pattern 33g are formed on substrate 200, impurities are ion-implanted. In particular, the string selection line pattern 33s, the plurality of word line patterns WP1-WPn, and the ground selection line pattern 33g direct ion species into the active regions between the string selection line pattern 33s, the plurality of word line patterns WP1 to WPn and the ground selection line pattern 33g, thereby forming low concentration impurity regions 35dc, 35d, 35, 35s, and 35sc, as shown in FIG. 4. In one embodiment, the low concentration impurity regions 35dc, 35d, 35, 35s and 35sc are formed by implanting the impurities at a low dose. For example, a dose between 10¹² cm⁻³ and 10¹⁴ cm⁻³, such as 10¹³ cm⁻³. In the various embodiments of the invention, the conductivity type of the impurities (i.e., N-type or P-type) is different from that of the substrate 200. Here, the low concentration impurity regions 35dc and 35d, which are adjacent to the string selection line pattern 33s and opposite the ground selection line pattern 33g, correspond to low concentration drain regions of the respective strings. Similarly, the low concentration impurity regions 35s and 35sc, which are adjacent to the ground selection line pattern 33g and opposite the string selection line pattern 33s, correspond to low concentration source regions of the respective strings.

As described above, the various embodiments provide an improved doping scheme for improving contact resistance, reducing parasitic string resistance, and preventing short-channel effects. To this end, a memory array in the various embodiments of the invention is arranged so that a spacer process can be used to selectively mask low concentration regions 35dc, 35d, 35, 35s, and 35sc during a subsequent implant process, such that high carrier concentration regions are formed only in portions of regions 35dc, 35d, 35s, and 35sc. The term “carrier concentration” as used herein with respect to a region doped with impurities is the average concentration of majority carriers in the region provided by the implanted impurities. In particular, the various embodiments of the invention provide for increasing a spacing between string selection line pattern 33s and any adjacent line patterns. Further, the various embodiments of the invention provide for also increasing a spacing between ground selection line pattern 33g and any adjacent line patterns. For example, as shown in FIGS. 2 and 4, rather than providing a the same spacing X2 between the string selection line pattern 33s, the plurality of word line patterns WP1 to WPn and the ground selection line pattern 33g, as in conventional NAND-type memory arrays, a spacing of X1>X2 is provided between string line selection pattern 33s and word line pattern WP1 or any other adjacent line patterns. Similarly, a spacing X1>X2 is also provided between ground line selection pattern 33g and word line pattern WPn or any other adjacent line patterns. For example, at a 43 nm node, X1 is at least 40 nm wider than X2.

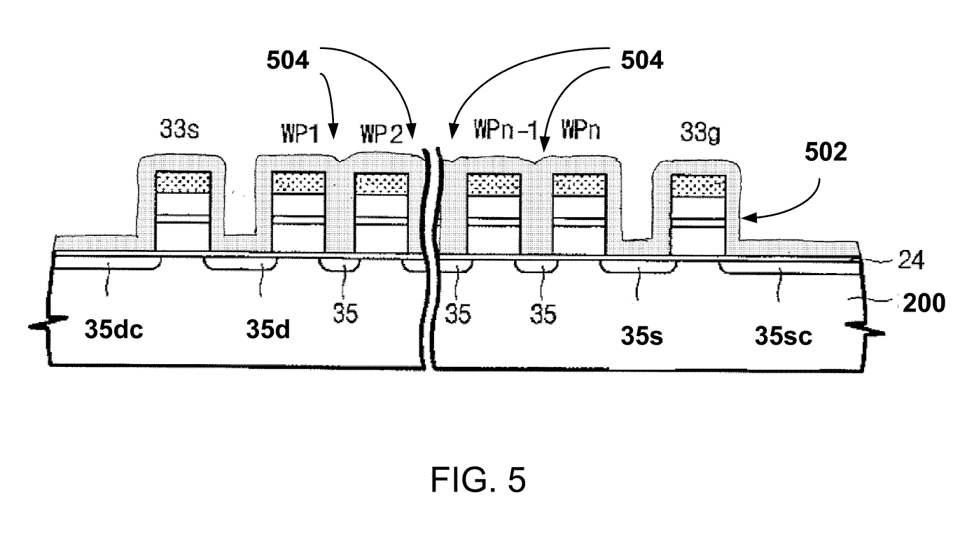

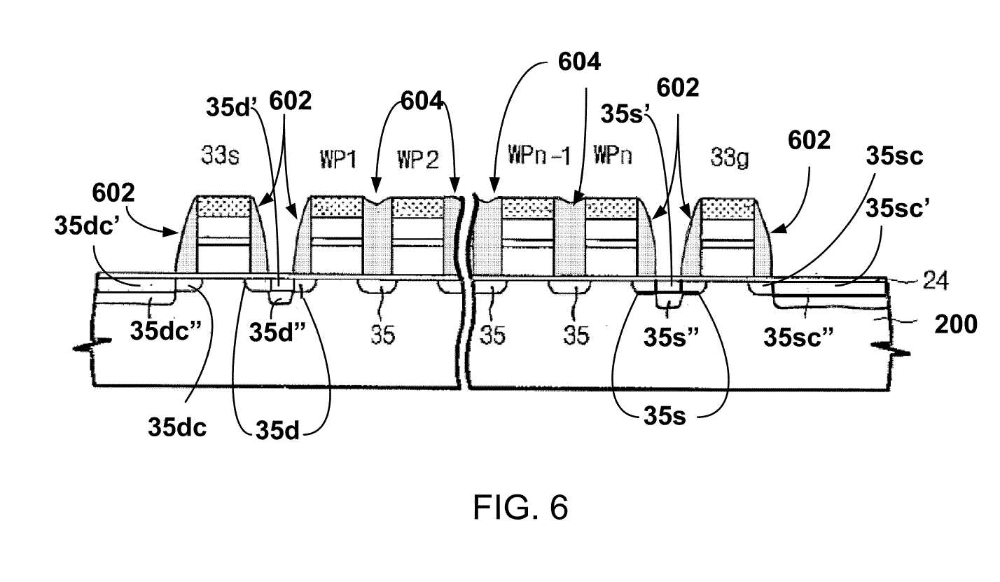

As a result spacings X1 and X2, a spacer-based LDD-type process can then be used to define portions of low concentration impurity regions 35dc, 35d, 35s, and 35sc into which additional impurities can be implanted. In particular, by careful selection of the thickness of the dielectric layer(s) sidewall spacers for low concentration impurity regions 35dc, 35d, 35s, and 35sc can be formed concurrently with an implant mask for low concentration impurity regions 35. Such an exemplary spacer process is illustrated below with respect to FIGS. 5 and 6.

FIG. 5 shows the result of forming a dielectric layer(s) on the structures shown in FIG. 4 in accordance with an embodiment of the invention. As shown in FIG. 5. a dielectric layer 502 is formed on substrate 200 over the string selection line pattern 33s, the plurality of word line patterns WP1 to WPn, the ground selection line pattern 33g, and low concentration impurity regions 35dc, 35d, 35, 35s, and 35sc. Dielectric layer 502 can comprise any dielectric composition, including one or more dielectric layers. For example dielectric layer 502 can comprise a silicon nitride layer, a silicon oxynitride layer, a silicon oxide layer, or any combination of layers thereof. However, the various embodiments of the invention are not limited in this regard and other dielectric layers can be used to provide the dielectric composition for dielectric layer 502.

In the various embodiments of the invention, the thickness of layer 502 is selected such that spaces 504 between the plurality of word lines WP1-WPn are substantially filled, or only leave a very narrow seam. Further, the thickness of layer 502 is selected such that a substantially conformal coverage of the string selection line pattern 33s, the plurality of word line patterns WP1 to WPn, the ground selection line pattern 33g, and low concentration impurity regions 35dc, 35d, 35s, and 35sc is also provided. For example a thickness between 100 Å and 1000 Å, such as 300 Å. Afterwards, the dielectric layer 502 can be etched to form masking regions in the NAND-type memory array and additional implantation of impurities can be performed. This is illustrated in FIG. 6.

FIG. 6 shows the results of performing a spacer etch process on the dielectric layer 502 of FIG. 5 and subsequent implantation of impurities in accordance with an embodiment of the invention. In the various embodiments of the invention, a spacer etch process can be performed on dielectric layer 502, such as an anisotropic etch process which preferably etches in a direction normal to substrate 200. As a result, the portion of dielectric layer 502 which are thinnest in the direction normal to substrate 200 are removed. For example, as shown in FIG. 6, portions of dielectric layer 502 on top of the string selection line pattern 33s, the plurality of word line patterns WP1 to WPn, and the ground selection line pattern 33g are substantially removed. Further, portions of dielectric layer 502 over low concentration impurity regions 35dc, 35d, 35s, and 35sc are also substantially removed. Other portions of dielectric layer 502 are not removed and thus result in masking portions for subsequent implants. For example, as shown in FIG. 6, sidewall masking regions 602 remain on the sidewalls of the string selection line pattern 33s, word line patterns WP1 and WPn, and the ground selection line pattern 33g. Further, cell masking regions 604 also remain between word line pattern WP1-WPn, or with a very narrow seam in the middle.

The configuration of masking regions 602 and 604 shown in FIG. 6 causes subsequent implants to limit significant changes in carrier concentration to the portions of the active areas between the string selection line pattern 33s, word line patterns WP1 and WPn, and the ground selection line pattern 33g. As a result, two or more regions, having different carrier concentrations can be formed. For example, the additional impurities implanted into low impurity concentration regions 35dc, 35d, 35s, and 35sc result in the formation of high doping regions 35dc′, 35d′, 35s′, and 35sc′, respectively, offset from the string selection line pattern 33s, word line patterns WP1 and WPn, and the ground selection line pattern 33g by the width of the sidewall masking regions 602. Thus, the carrier concentration in these regions is higher than that of the portions of low impurity concentration regions 35dc, 35d, 35, 35s, and 35sc masked by masking regions 602 and 604. In some embodiments, the implantation of additional impurities (e.g., higher mass or higher energies) may result in the formation of deep doping regions 35dc″, 35d″, 35s″, and 35sc″. These regions can also offset from the string selection line pattern 33s, word line patterns WP1 and WPn, and the ground selection line pattern 33g by the width of the sidewall masking regions 602, but are also offset from a top surface of substrate 200 by the depth of high doping regions 35dc′, 35d′, 35s′, and 35sc′, respectively. Additionally these regions have a carrier concentration that is greater than the carrier concentration in low impurity concentration regions 35dc, 35d, 35, 35s, and 35sc but less than the carrier concentration in high doping regions 35dc′, 35d′, 35s′, and 35sc′.

As a result, the array 100 provides high carrier concentration contact regions for the string selection line pattern 33s and ground selection line pattern 33g in regions 35dc′ and 35sc′, respectively. Further, deep junctions for these contact regions can be provided by forming regions 35dc″ and 35sc″. As a result, sufficiently high doping is provided for improving contact resistance and the formation of silicides. Additionally, the array 100 also provides high carrier concentration regions between the string selection line pattern 33s and word line pattern WP1 and the ground selection line pattern 33g and WPn using regions high doping regions 35d′ and 35s′, respectively. As a result, parasitic string resistance is reduced. Finally, since only low carrier concentration regions 35 are formed between the plurality of word lines WP1-WPn and low carrier concentration regions 35d and 35s abut word lines WP1 and WPn, respectively, short channel effects for the memory cells are reduced.

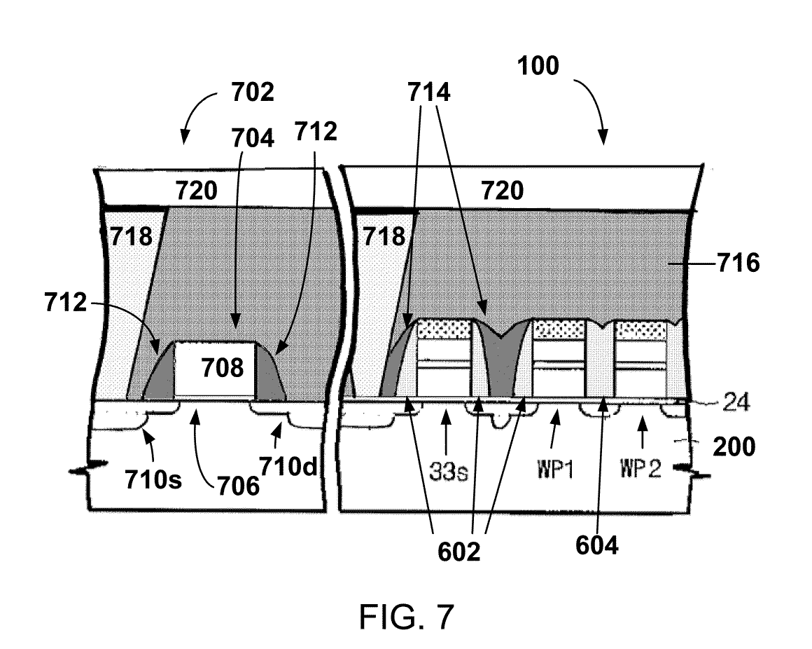

In some embodiments of the invention, the spacer process described above can be used to define the spacers and implants for all devices on substrate 200. However, in other embodiments of the invention, the spacer process described above can be in addition to other processes for other devices on substrate 200. Such a process is useful when a different set of implants is needed for devices outside the memory array. The result of such a process is illustrated in FIG. 7.

FIG. 7 is a portion of a cross section view of substrate 200 after NAND-type memory array 100 and other device regions 702 are formed thereon. As shown in FIG. 7, the device region 702 can include one or more metal oxide semiconductor field effect transistor (MOSFET) devices 704 formed on substrate 200 alongside array 100. However, the invention is not limited in this regard. Rather, the device region 702 can also include other types of devices, including, but not limited to, other types of CMOS devices, bipolar devices, BiCMOS devices, and MEMS devices.

The device region 702 is formed as follows. Once array 100 is formed as described above with respect to FIGS. 1-6, manufacturing of device region 702 can begin. In some embodiments, when isolation features are formed to define the active areas in array 100, isolation features are concurrently formed in device region 702 to define the active areas for device region 702. However, the invention is not limited in this regard and the isolation features for the device region 702 can be formed at a different time. Afterwards, a gate oxide layer 706 can be formed in the active areas of device region 702, followed by formation of a gate electrode pattern 708. The gate electrode pattern 708 can include, for example, a polysilicon or amorphous silicon layer. Together, the gate oxide layer 706 and the gate electrode pattern 708 define a gate for MOSFET 704.

After the gate for MOSFET 704 is defined, a source region 710s and a drain region 710d can be defined using one or more implants. In the embodiment illustrated in FIG. 7, an LDD process is used. That is, after a first implant forms a low impurity concentration region abutting the gate oxide 706 and gate electrode 708 layers of MOSFET 704, a dielectric layer is deposited thereon. Afterwards, the dielectric layer is processed to form sidewall masking regions 712 on MOSFET 704. For example, an anisotropic etch process can be used. In the various embodiments of the invention, the dielectric composition of sidewall masking regions 712 can be the same or different as that of masking regions 602 and 604 in array 100. In the various embodiments of the invention, the thickness of the dielectric layer for forming sidewall masking regions 712 can also be selected to provide further masking in the array 100. That is, the thickness of the dielectric layer is selected such that any remaining space between facing sidewall regions 602 is substantially filled and such that a substantially conformal coverage of all other features provided. Accordingly, when the dielectric layer is processed, additional masking regions 714 are formed between sidewall regions 602. The additional masking regions thus prevent additional dopants from significantly altering the carrier concentrations in S/D regions abutting the selection line patterns 33s or 33g in the array 100.

Once the S/D regions have been formed in the device region 702 and the memory array 100, processing of substrate 200 can proceed to provide one or more levels of metallization for connection array 100 to device region 702 or to external devices. For example, a dielectric layer 716 can be formed over array 100 and device region 702. Afterwards, metal vias 718 can be formed in dielectric layer 716 to contact S/D regions on substrate 200. For example, as shown in FIG. 7, vias 718 can contact contact region 710s and a contact region for string selection line pattern 33s. Afterwards, metal lines 720 can be provided to interconnect array 100 and device region 702 or to connect device region 702 and/or array to one or more external components. This process can be repeated to provide additional levels of metallization.

In the various embodiments of the invention, any type of metallization process can be used. For example, conventional aluminum and copper alloy metallization processes can be used, including multi-layer processes. However, the invention is not limited in this regard and other metallization processes can also be used. Further, blanket dielectric layer 716 can comprise one or more layers of any type of intermetal dielectric materials. For example, such materials can include silicon oxide layers, phosphosilicate glass layers, borophosphosilicate glass layers, to name a few. However the invention is not limited in this regard and any other types of intermetal dielectric layer materials can be used, including low dielectric constant (low-k) materials.

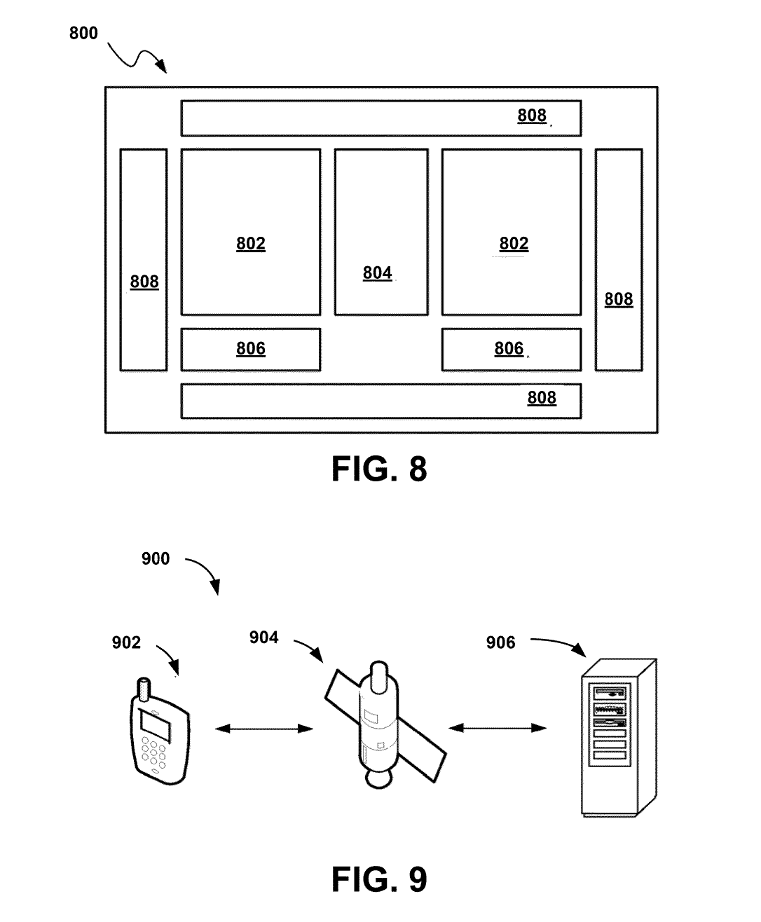

Referring now to FIG. 8, therein is shown a plan view of a device 800 in accordance with an embodiment of the invention. The device 800 is an electronic device including one or more memory system cell systems 802 and other components 804-808. The various components of device 800 can be formed on a same substrate or housing, but the various embodiments of the invention are not limited in this regard.

The memory cell systems 802 can include individually addressable, substantially identical memory arrays, such as memory array 100 of FIGS. 1-7. The other components 804-808 can include input/output (I/O) circuitry and programming circuitry for individually and selectively addressing the memory cell system 100. For example, the programming circuitry can include one or more x-decoders 804 and y-decoders 806, cooperating with I/O circuitry 808 for connecting to memory cells and effecting designated operations on the memory cells. For example, such operations can include programming, reading, and erasing, and deriving necessary voltages to effect such operations.

For illustrative purposes, the device 800 is shown as a memory device, although it is understood that the device 800 may other semiconductor devices having other functional blocks, such as a digital logic block, a processor, or other types of memories. In some embodiments of the invention, the device 800 can be as single semiconductor device. However, the invention is not limited in this regard. For example, in other embodiments of the invention, the device 800 can be a multichip module with other types of devices of similar or different semiconductor technologies, such as power devices or microelectromechanical systems (MEMS). In yet other embodiments of the invention, the device 800 may be a board level (i.e., formed on a printed circuit board) electronic device including a memory array in accordance with the various embodiments of the invention.

Referring now to FIG. 9, therein is shown an exemplary electronic systems 900 in accordance with an embodiment of the invention. A mobile or non-mobile terrestrial based communications device 902, an airborne or space borne communications device 904, and a computing system 906 are examples of the electronic systems 900 using memory arrays in accordance with the various embodiments of the invention. In particular, the electronic systems 900 may be any electronic devices or systems that performs any function for the creation, transportation, storage, and consumption of information. For example, the terrestrial communications device 902 may create information by transmitting data to the spaceborne communications device 904. The communications device 904 can then transport the information to the computing system 906. The computing system 906 may be used to store the information. The terrestrial communications device 902 may also consume information sent from the spaceborne communications device 904.

In light of the forgoing description of the invention, it should be recognized that some aspects of the invention can be realized in hardware, software, or a combination of hardware and software. A typical combination of hardware and software could be a general purpose computer processing unit, with a computer program that, when being loaded and executed, controls the computer processing unit such that it carries out the methods described herein. Of course, an application specific integrated circuit (ASIC), and/or a field programmable gate array (FPGA) could also be used to achieve a similar result.

While various embodiments of the invention have been described above, it should be understood that they have been presented by way of example only, and not limitation. Numerous changes to the disclosed embodiments can be made in accordance with the disclosure herein without departing from the spirit or scope of the invention. For example, the various portions of methods 300, 400, and 500 can be performed by a controller of device 200, a processing element in system 100, or any combination thereof Thus, the breadth and scope of the invention should not be limited by any of the above described embodiments. Rather, the scope of the invention should be defined in accordance with the following claims and their equivalents.

Although the invention has been illustrated and described with respect to one or more implementations, equivalent alterations and modifications will occur to others having ordinary skill in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

The terminology used herein is for the purpose of describing particular embodiments only and is not intended to be limiting of the invention. As used herein, the singular forms “a”, “an” and “the” are intended to include the plural forms as well, unless the context clearly indicates otherwise. Furthermore, to the extent that the terms “including”, “includes”, “having”, “has”, “with”, or variants thereof are used in either the detailed description and/or the claims, such terms are intended to be inclusive in a manner similar to the term “comprising.”

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

We claim:

1. An electronic device, comprising:
a substrate having a plurality of isolation features defining at least first active regions coextending over a surface of said substrate;
a plurality of line patterns coextending over the first active regions, said plurality of line patterns comprising a string selection line, a ground selection line, and a plurality of word lines between the string selection line and the ground selection line;
first implant regions of a first conductivity type formed in the first active regions between the plurality of word lines and having a first carrier concentration; and
second implant regions of said first conductivity type formed in the first active regions between edge word lines of said plurality of word lines and an adjacent one of said string selection line and said ground selection line, said second implant regions comprising a low doping portion abutting said edge word lines and having said first carrier concentration and a high doping portion spaced from said edge word line by said low doping portion and having a second carrier concentration greater than said first carrier concentration.

2. The integrated circuit of claim 1, where the plurality of word lines have a first line spacing, and wherein the plurality of word lines are separated from the string selection line and the ground selection line by a second line spacing greater than the first line spacing.

3. The integrated circuit of claim 1, wherein said high doping portion comprises:
a main portion abutting a top of said surface and having said second carrier concentration;
a deep portion spaced from said top of said surface by said lightly doped portion and said main portion, said deep portion having a third carrier concentration which is greater than said first carrier concentration but less than said second carrier concentration.

4. The integrated circuit of claim 1, further comprising a plurality of insulating regions comprising a first dielectric composition, said plurality of insulating regions comprising:
a sidewall insulating regions abutting the sidewalls of said string selection line, said ground selection line, and said edge word lines;
array insulating regions disposed between said plurality of word lines, each of said space insulating regions occupying a majority of a space between two adjacent ones of said plurality of word lines.

5. The integrated circuit of claim 1, further comprising:
a first plurality of insulating regions comprising a first dielectric composition, said plurality of insulating regions comprising sidewall portions abutting the sidewalls of said string selection line, said ground selection line, and said edge word lines and array portions occupying a majority of each space between adjacent ones of said plurality of word lines;
a plurality of device lines crossing at least second active regions defined by said plurality of isolation regions on said surface of said substrate; and
a second plurality of insulating regions comprising a second dielectric composition, said second plurality of insulating regions abutting the sidewalls of said plurality of device lines.

6. The integrated circuit of claim 1, wherein said string selection line and said ground selection line each comprise a multi-layer gate stack having a tunnel dielectric layer.

7. The integrated circuit of claim 1, further comprising:
a control element communicatively coupled said plurality of lines and said plurality of active areas to provide a memory system; and
an electronic device communicatively coupled to said memory system.

8. A method of manufacturing an electronic system including memory cell devices, the method comprising:
obtaining a substrate having a plurality of isolation features defining at least first active regions coextending over a surface of said substrate;
forming a plurality of line patterns coextending over the first active regions, said plurality of line patterns comprising a string selection line, a ground selection line, and a plurality of word lines between the string selection line and the ground selection line;
forming first implant regions having a first carrier concentration by implanting at least one ion species of a first conductivity type in the first active regions between the plurality of word lines; and
forming second implant regions comprising a high doping portion and a low doping portion by implanting at least one ion species of said first conductivity type in the first active regions between edge word lines of said plurality of word lines and an adjacent one of said string selection line and said ground selection line,
wherein said low doping portion abuts said edge word lines and has said first carrier concentration, and wherein said high doping portion is spaced from said edge word line by said low doping portion and has a second carrier concentration greater than said first carrier concentration.

9. The method of claim 8, further comprising arranging the plurality of word lines to have a first line spacing and to be separated from the string selection line and the ground selection line by a second line spacing greater than the first line spacing.

10. The method of claim 8, wherein said forming said second implant regions further comprises selecting said high doping portion to comprise a main portion abutting a top of said surface and having said second carrier concentration, and a deep portion spaced from said top of said surface by said lightly doped portion and said main portion, said deep portion having a third carrier concentration which is greater than said first carrier concentration but less than said second carrier concentration.

11. The method of claim 8, wherein said forming said second implant regions further comprises:
prior to said implanting, forming a plurality of insulating regions of a first dielectric composition, said plurality of insulating regions comprising sidewall masking regions abutting the sidewalls of said string selection line, said ground selection line, and said edge word lines, and cell regions disposed between said plurality of word lines, each of said space insulating regions occupying a majority of a space between two adjacent ones of said plurality of word lines.

12. The method of claim 8, further comprising:
forming a plurality of device lines crossing at least second active regions defined by said plurality of isolation regions on said surface of said substrate; and
selectively forming a second plurality of insulating regions abutting the sidewalls of said plurality of device lines.

13. The method of claim 8, wherein said forming said plurality of line patterns further comprises forming said string selection line and said ground selection line to provide a multi-layer gate stack having a tunnel dielectric layer.

14. The method of claim 8, further comprising:
communicatively coupling a control element to said plurality of lines and said plurality of active areas to provide a memory system; and
forming an electronic system with said memory system.

15. An integrated circuit, comprising:
a substrate having a semiconducting surface;
a plurality of isolation features defining at least first active regions in said semiconducting surface that coextend over said semiconducting surface;
a plurality of line patterns coextending over the first active regions, said plurality of line patterns comprising a string selection line, a ground selection line, and a plurality of word lines between the string selection line and the ground selection line;
first implant regions of a first conductivity type formed in the first active regions between the plurality of word lines and having a first carrier concentration; and
second implant regions of said first conductivity type formed in the first active regions between edge word lines of said plurality of word lines and an adjacent one of said string selection line and said ground selection line, said second implant regions comprising a low doping portion abutting said edge word lines and having said first carrier concentration and a high doping portion spaced from said edge word line by said low doping portion and having a second carrier concentration greater than said first carrier concentration.

16. The integrated circuit of claim 15, where the plurality of word lines have a first line spacing, and wherein the plurality of word lines are separated from the string selection line and the ground selection line by a second line spacing greater than the first line spacing.

17. The integrated circuit of claim 15, wherein said high doping portion comprises:
a main portion abutting a top of said semiconducting surface and having said second carrier concentration;
a deep portion spaced from said top of said semiconducting surface by said lightly doped portion and said main portion, said deep portion having a third carrier concentration which is greater than said first carrier concentration but less than said second carrier concentration.

18. The integrated circuit of claim 15, further comprising a plurality of insulating regions comprising a first dielectric composition, said plurality of insulating regions comprising:
a sidewall insulating regions abutting the sidewalls of said string selection line, said ground selection line, and said edge word lines;
array insulating regions disposed between said plurality of word lines, each of said space insulating regions occupying a majority of a space between two adjacent ones of said plurality of word lines.

19. The integrated circuit of claim 15, further comprising:
a first plurality of insulating regions comprising a first dielectric composition, said plurality of insulating regions comprising sidewall portions abutting the sidewalls of said string selection line, said ground selection line, and said edge word lines and array portions occupying a majority of each space between adjacent ones of said plurality of word lines;
a plurality of device lines crossing at least second active regions in said semiconducting surface defined by said plurality of isolation regions; and
a second plurality of insulating regions comprising a second dielectric composition, said second plurality of insulating regions abutting the sidewalls of said plurality of device lines.

20. The integrated circuit of claim 15, further comprising:
a control element communicatively coupled said plurality of lines and said plurality of active areas to provide a memory system; and
an electronic device communicatively coupled to said memory system.
